(19) United States
(12) Patent Application Publication
(10) Pub. No.: US 2024/0431156 A1
(43) Pub. Date: Dec. 26, 2024

(54) LIGHT EMITTING DEVICE, DISPLAY DEVICE, PHOTOELECTRIC CONVERSION DEVICE, ELECTRONIC APPARATUS, ILLUMINATION DEVICE, AND MOVING BODY

(71) Applicant: CANON KABUSHIKI KAISHA, Tokyo (JP)

(72) Inventors: AKINORI MAKAINO, Kanagawa (JP); TASUKU KANEDA, Kanagawa (JP)

(21) Appl. No.: 18/829,611

(22) Filed: Sep. 10, 2024

Related U.S. Application Data
(63) Continuation of application No. PCT/JP2023/007943, filed on Mar. 3, 2023.

(30) Foreign Application Priority Data
Apr. 8, 2022 (JP) 2022-064649
Dec. 22, 2022 (JP) 2022-205995

(51) Int. Cl. H10K 59/124

(52) U.S. Cl. CPC H10K 59/124

(57) ABSTRACT

A light emitting device in which a pixel including a light emitting element and transistors configured to operate the light emitting element are arranged is provided. The transistors include a first transistor including one of a source region and a drain region connected to the light emitting element, and a second transistor including a source region and a drain region not connected to the light emitting element. A first silicide is arranged in a first diffusion region functioning as one of the source region and the drain region of the first transistor, a second silicide is arranged in a second diffusion region functioning as one of the source region and the drain region of the second transistor, and a diffusion coefficient of a metal contained in the first silicide is smaller than a diffusion coefficient of a metal contained in the second silicide.

### CROSS-REFERENCE TO RELATED APPLICATIONS

This application is a Continuation of International Patent Application No. PCT/JP2023/007943, filed Mar. 3, 2023, which claims the benefit of Japanese Patent Applications No. 2022-064649, filed Apr. 8, 2022, and Japanese Patent Applications No. 2022-205995, filed Dec. 22, 2022, all of which are hereby incorporated by reference herein in their entirety.

### BACKGROUND OF THE INVENTION

### Field of the Invention

The present invention relates to a light emitting device, a display device, a photoelectric conversion device, an electronic apparatus, an illumination device, and a moving body.

### Background Art

Along with an increase in resolution of a pixel of a light emitting device using a self-light emitting element such as an organic electroluminescence (EL) element, a transistor for operating the light emitting element arranged in the pixel is miniaturized, and the off-leakage current of the transistor increases. PTL 1 describes that, in order to suppress fluctuation of a driving current caused by the leakage current of a switching transistor connected to the gate of a driving transistor, the LDD length of the switching transistor is made longer than the LDD length of the driving transistor.

### CITATION LIST

### Patent Literature

PTL 1: Japanese Patent Laid-Open No. 2008-281671

One factor of the increase of the off-leakage current due to miniaturization of a transistor can be the increase of a junction leakage in a p-n junction portion between a well and a diffusion region (high concentration region) functioning as the source or drain of the transistor. If a leakage current increases in a transistor whose diffusion region is connected to a light emitting element, the leakage current flows into the light emitting element, and this causes a degradation in image quality such as a decrease in contrast.

The present invention has as its object to provide a technique advantageous in suppressing degradation of image quality.

### SUMMARY OF THE INVENTION

According to some embodiments, a light emitting device in which a pixel including a light emitting element and a plurality of transistors configured to operate the light emitting element are arranged on a substrate, wherein the plurality of transistors comprise a first transistor including one of a source region and a drain region connected to the light emitting element, and a second transistor including a source region and a drain region not connected to the light emitting element, a first silicide is arranged in a first diffusion region functioning as one of the source region and the drain region of the first transistor, a second silicide is arranged in a second diffusion region functioning as one of the source region and the drain region of the second transistor, and a diffusion coefficient of a metal contained in the first silicide to silicon is smaller than a diffusion coefficient of a metal contained in the second silicide to silicon, is provided.

Further features of the present invention will become apparent from the following description of exemplary embodiments with reference to the attached drawings.

### BRIEF DESCRIPTION OF THE DRAWINGS

The accompanying drawings, which are incorporated in and constitute a part of the specification, illustrate embodiments of the invention and, together with the description, serve to explain principles of the invention.

FIG. 1 is a view showing an example of the arrangement of a light emitting device according to an embodiment.

FIG. 2 is a view showing an example of the arrangement of a pixel of the light emitting device shown in FIG. 1.

FIG. 3 is a top view showing an example of the arrangement of transistors of the pixel shown in FIG. 2.

FIG. 4 is a sectional view taken along a line A-A′ in FIG. 3.

FIG. 5 is a sectional view taken along the line A-A′ in FIG. 3.

FIG. 6 is a sectional view showing an example of arrangement of transistors of a driving unit of the light emitting device shown in FIG. 1.

FIG. 7 is a sectional view taken along a line A-A′ in FIG. 3.

FIG. 8 is a top view showing an example of the arrangement of transistors of the pixel shown in FIG. 2.

FIG. 9 is a sectional view taken along a line B-B′ in FIG. 8.

FIG. 10 is a sectional view taken along the line A-A′ in FIG. 3.

FIG. 11A is a view for explaining a manufacturing method of the light emitting device shown in FIG. 1.

FIG. 11B is a view for explaining the manufacturing method of the light emitting device shown in FIG. 1.

FIG. 11C is a view for explaining the manufacturing method of the light emitting device shown in FIG. 1.

FIG. 12A is a view for explaining the manufacturing method of the light emitting device shown in FIG. 1.

FIG. 12B is a view for explaining the manufacturing method of the light emitting device shown in FIG. 1.

FIG. 12C is a view for explaining the manufacturing method of the light emitting device shown in FIG. 1.

FIG. 13A is a view for explaining the manufacturing method of the light emitting device shown in FIG. 1.

FIG. 13B is a view for explaining the manufacturing method of the light emitting device shown in FIG. 1.

FIG. 14A is a view for explaining the manufacturing method of the light emitting device shown in FIG. 1.

FIG. 14B is a view for explaining the manufacturing method of the light emitting device shown in FIG. 1.

FIG. 15 is a view showing an example of the arrangement of the pixel of the light emitting device shown in FIG. 1.

FIG. 16 is a view showing an example of a display device using the light emitting device according to the embodiment.

FIG. 17 is a view showing an example of a photoelectric conversion device using the light emitting device according to the embodiment.

FIG. 18 is a view showing an example of an electronic apparatus using the light emitting device according to the embodiment.

FIG. 19A is a view showing an example of a display device using the light emitting device according to the embodiment.

FIG. 19B is a view showing an example of a display device using the light emitting device according to the embodiment.

FIG. 20 is a view showing an example of an illumination device using the light emitting device according to the embodiment.

FIG. 21 is a view showing an example of a moving body using the light emitting device according to the embodiment.

FIG. 22A is a view showing an example of a wearable device using the light emitting device according to the embodiment.

FIG. 22B is a view showing an example of a wearable device using the light emitting device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

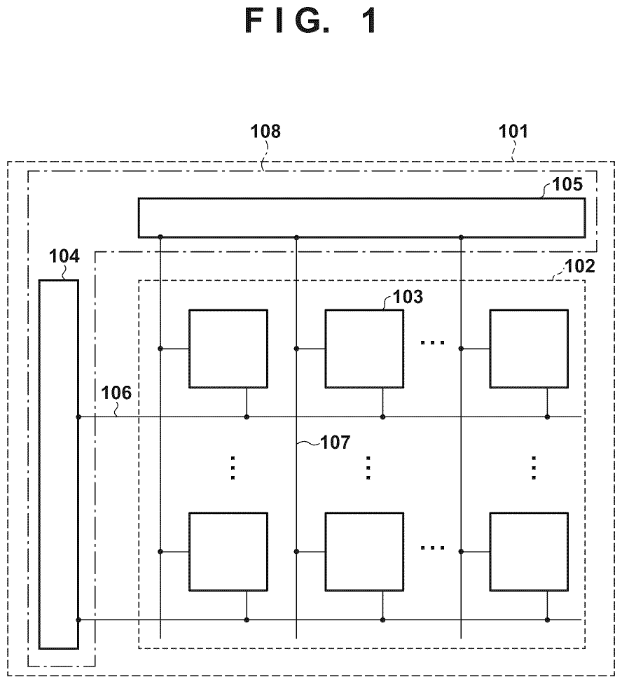

With reference to FIGS. 1 to 15, a light emitting device according to an embodiment of the present disclosure will be described. FIG. 1 is a schematic view showing an example of the arrangement of a light emitting device 101 in this embodiment. The light emitting device 101 includes a pixel array 102, and a driving unit arranged around the pixel array 102. A plurality of pixels 103 two-dimensionally arranged in a matrix are arranged in the pixel array 102. The pixel 103 includes a light emitting element and a plurality of transistors for operating the light emitting element, which are formed on a substrate. Details will be described later.

The driving unit is a circuit for driving the pixels 103. For example, the driving unit includes a vertical scanning circuit 104 and a signal output circuit 105. In the pixel array 102, a scanning line 106 is arranged for each pixel row along a row direction. In addition, a signal line 107 is arranged for each pixel column along a column direction.

The scanning line 106 is connected to the output terminal in the corresponding row in the vertical scanning circuit 104. The signal line 107 is connected to the output terminal of the signal output circuit 105. When writing a video signal in each pixel 103 arranged in the pixel array 102, the vertical scanning circuit 104 supplies a write control signal to the scanning line 106. The signal output circuit 105 outputs a luminance signal having a voltage corresponding to digital display data supplied from the outside.

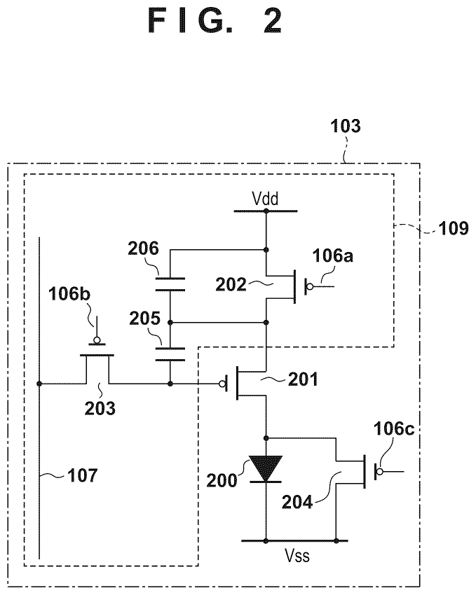

FIG. 2 is a circuit diagram showing an example of the arrangement of the pixel 103 included in the light emitting device 101. As shown in FIG. 2, the pixel 103 includes a light emitting element 200 and a plurality of transistors for operating the light emitting element. The light emitting element 200 includes an organic layer including a light emitting layer between electrodes of an anode and a cathode. The light emitting element 200 may be an organic electroluminescence (EL) element. The organic layer may include, in addition to the light emitting layer, one or more of a hole injection layer, a hole transport layer, an electron injection layer, an electron transport layer, and an electron generation layer, as appropriate.

In the pixel 103, a driving transistor 201 and a write transistor 203 are arranged as the plurality of transistors for operating the light emitting element. Further, in the arrangement shown in FIG. 2, a light emission control transistor 202 and a reset transistor 204 are arranged as the plurality of transistors. Two electrostatic capacitances 205 and 206 are also arranged in the pixel 103. A power supply potential Vdd and a power supply potential Vss are supplied to the pixel 103.

Each of four transistors arranged in the pixel 103 can be a MOSFET. Control signals for controlling the transistors are input to the gate electrodes of the light emission control transistor 202, the write transistor 203, and the reset transistor 204 via three scanning lines 106a, 106b, and 106c, respectively. The signal line 107 is connected to the source region of the write transistor 203. When the write transistor 203 is set in the ON state (conductive state), the voltage value of the signal line 107 is input to the gate electrode of the driving transistor 201. Depending on this signal voltage, the current value between the source region and drain region of the driving transistor 201 is decided, and the light emission luminance of the light emitting element 200 is controlled.

The drain region of the driving transistor 201 is connected to the anode of the light emitting element 200 and the source region of the reset transistor 204. When the reset transistor 204 is set in the ON state, no current flows through the light emitting element 200 so no light emission occurs. The cathode of the light emitting element 200 and the drain region of the reset transistor 204 have the same potential (power supply potential Vss).

The power supply potential Vss may be, for example, a ground potential. For example, there may be a potential difference of 10 V between the power supply potential Vdd and the power supply potential Vss. However, the power supply potential Vdd and the power supply potential Vss are not limited to this. Setting of the power supply potential Vdd and the power supply potential Vss is decided, as appropriate, in accordance with the conversion characteristic (light emission characteristic) of the light emitting element 200.

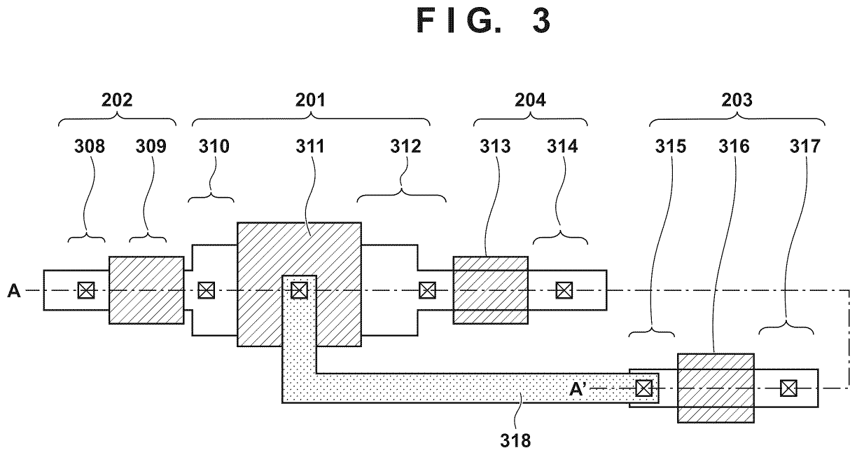

FIG. 3 shows a top view including the transistors arranged in the pixel 103 to operate the light emitting element 200 in this embodiment. The driving transistor 201 includes a gate electrode 311, a diffusion region 310 functioning as the source region (the diffusion region can also be referred to as a high concentration region), and a diffusion region 312 functioning as the drain region. The light emission control transistor 202 includes a gate electrode 309 and a diffusion region 308 functioning as the source region. The diffusion region 308 is connected to the power supply potential Vdd. In the circuit shown in FIG. 2, the drain region of the light emission control transistor 202 is electrically connected to the source region of the driving transistor 201, and arranged as the diffusion region 310 functioning as the source region of the driving transistor 201. The reset transistor 204 includes a gate electrode 313 and a diffusion region 314 functioning as the drain region. The diffusion region 314 is connected to the power supply potential Vss. In the circuit shown in FIG. 2, the drain region of the driving transistor 201 is electrically connected to the source region of the reset transistor 204, and arranged as the diffusion region 312 functioning as the drain region of the driving transistor 201. The write transistor 203 includes a gate electrode 316, a diffusion region 317 functioning as the source region, and a diffusion region 315 functioning as the drain region. The diffusion region 315 functioning as the drain region of the write transistor 203 is electrically connected to the gate electrode 311 of the driving transistor 201 as shown in FIG. 2. In the arrangement shown in FIG. 3, they are electrically connected by a conductive pattern 318.

Since FIG. 3 is a top view of the semiconductor substrate, not all the connections shown in the circuit diagram of FIG. 2 are shown. However, a wiring layer is stacked on the above-described respective transistors arranged on the substrate, and the circuit shown in FIG. 2 is implemented by wiring patterns, contact plugs, and the like.

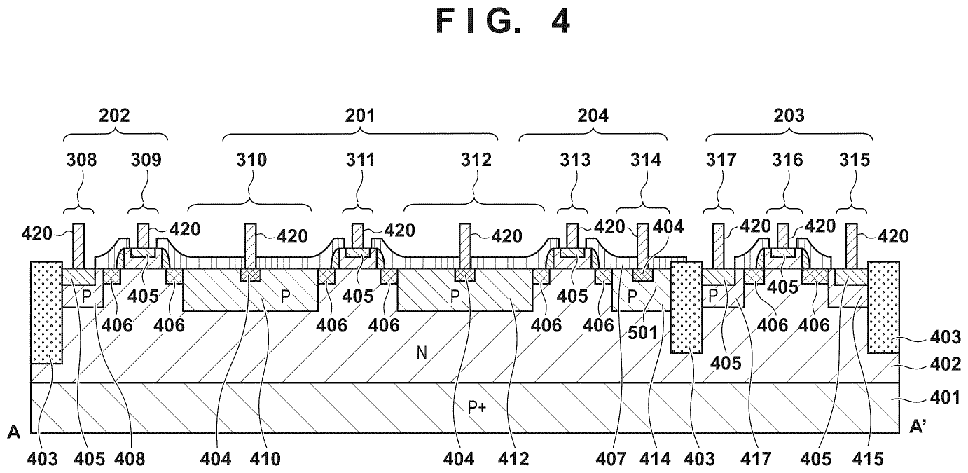

FIG. 4 is a sectional view taken along a line A-A′ shown in FIG. 3. In this embodiment, a description will be given assuming that each of the driving transistor 201, the light emission control transistor 202, the write transistor 203, and the reset transistor 204 is formed by a PMOS transistor. However, the present invention is not limited to this, and the arrangement described below may be adjusted, as appropriate, in accordance with the conductivity type of each transistor.

In this embodiment, an n-type well layer 402 is arranged on the upper surface side of a single-crystal p-type silicon substrate 401. The above-described driving transistor 201, light emission control transistor 202, write transistor 203, and reset transistor 204 are arranged in the well layer 402. The well layer 402 is electrically connected to the power supply potential Vdd. The transistors not sharing the diffusion region functioning as the drain region or the source region are electrically isolated by an insulating isolation structure 403. In the arrangement shown in FIG. 4, an STI structure is shown as the insulating isolation structure 403, but the present invention is not limited to this, and an appropriate structure may be used for electrical isolation. In this embodiment, the STI structure used as the insulating isolation structure 403 is made of silicon oxide, and can be formed in a range of, for example, 0.2 μm to 1.0 μm in the depth direction from the surface of the n-type well layer 402. The driving transistor 201, the light emission control transistor 202, the write transistor 203, and the reset transistor 204 include the gate electrodes 311, 309, 316, and 313, respectively, made of polycrystalline silicon on a thin insulating film formed on the surface of the well layer 402. The diffusion regions 310, 312, 308, 315, 317, and 314 arranged in the driving transistor 201, the light emission control transistor 202, the write transistor 203, and the reset transistor 204 are p-type diffusion regions, and electrically connected to the wiring patterns arranged in the above-described wiring layer, as appropriate, using the contact plugs and the like.

In the arrangement shown in FIG. 4, each of the driving transistor 201, the light emission control transistor 202, the write transistor 203, and the reset transistor 204 includes an LDD structure (region 406). In other words, each of the driving transistor 201, the light emission control transistor 202, the write transistor 203, and the reset transistor 204 has a so-called offset structure extending from the side wall lower portion of the gate electrode to the side of the source region or the drain region. That is, the diffusion regions 310 and 312 of the driving transistor 201 include regions 410 and 412, and the regions 406 each arranged between corresponding one of the regions 410 and 412 and the channel region of the driving transistor 201 and having a lower impurity concentration than the regions 410 and 412. The diffusion region 308 of the light emission control transistor 202 includes a region 408, and the region 406 arranged between the region 408 and the channel region of the light emission control transistor 202 and having a lower impurity concentration than the region 408. The diffusion regions 315 and 317 of the write transistor 203 include regions 415 and 417, and the regions 406 each being arranged between corresponding one of the regions 415 and 417 and the channel region of the write transistor 203 and having a lower impurity concentration than the regions 415 and 417. The diffusion region 314 of the reset transistor 204 includes a region 414, and the region 406 arranged between the region 414 and the channel region of the reset transistor 204 and having a lower impurity concentration than the region 414. However, the present invention is not limited to this, and some transistors of the driving transistor 201, the light emission control transistor 202, the write transistor 203, and the reset transistor 204 may have the LDD structure. Alternatively, the driving transistor 201, the light emission control transistor 202, the write transistor 203, and the reset transistor 204 may not have the LDD structure.

The light emitting device 101 in this embodiment is driven as described below. A scanning signal via the scanning line 106a controls the gate electrode 309 of the light emission control transistor 202 via the wiring pattern. When the light emission control transistor 202 is in the ON state, the power supply potential Vdd is applied to the diffusion region 310 functioning as the source region of the driving transistor 201. A scanning signal via the scanning line 106b controls the gate electrode 316 of the write transistor 203 via the wiring pattern. When the write transistor 203 is in the ON state, a signal potential via the signal line 107 is applied to the diffusion region 315 functioning as the drain region of the write transistor 203 and the gate electrode 311 of the driving transistor 201. Since the write transistor 203 is insulated from the driving transistor 201 by the STI structure, the diffusion region 315 functioning as the drain region of the write transistor 203 and the gate electrode 311 of the driving transistor 201 are connected via the above-described conductive pattern 318. In accordance with the potential of the gate electrode 311 of the driving transistor 201, a current to the diffusion region 312 functioning as the drain region of the driving transistor 201, that is, a current flowing to the anode of the light emitting element 200 is controlled, and the light emission luminance of the light emitting element 200 is decided. A scanning signal via the scanning line 106c controls the gate electrode 313 of the reset transistor 204 via the wiring pattern. When the reset transistor 204 is in the ON state, the anode electrically connected to the diffusion region 312 functioning as the source region of the reset transistor is set to the power supply potential Vss. The same power supply potential Vss is supplied to the cathode of the light emitting element 200 in all the pixels 103. Accordingly, when the reset transistor 204 is in the ON state, the potential difference between the anode and cathode of the light emitting element 200 decreases, and light emission stops.

Here, due to miniaturization of the transistor or the like, when the driving transistor 201 is in the OFF state (non-conductive state), an off-leakage current caused by an electric field generated by the potential difference between the potential of the diffusion region 312 of the driving transistor 201 and the potential of the n-type well layer 402 may increase. An off-leakage current between the diffusion region 310 of the driving transistor 201 and the diffusion region 312 may also increase. In these cases, even though the driving transistor 201 is in the OFF state, a current may flow through the light emitting element 200 and cause light emission of the light emitting element 200, and this can lead to a decrease in contrast.

To prevent this, in this embodiment, as shown in FIG. 4, a metal forming a silicide arranged in the diffusion region is changed between the transistors arranged in the pixel 103. More specifically, the plurality of transistors arranged in the pixel 103 include the first transistor including a source region or a drain region connected to the light emitting element 200, and the second transistor including a source region and a drain region not connected to the light emitting element 200. In this embodiment, the driving transistor 201 and the reset transistor 204 correspond to the first transistor. The light emission control transistor 202 and the write transistor 203 correspond to the second transistor. A silicide 404 is arranged in each of the diffusion regions 310, 312, and 314 functioning as the source region or the drain region of the driving transistor 201 and the reset transistor 204. A silicide 405 is arranged in each of the diffusion regions 308, 315, and 317 functioning as the source region or the drain region of the light emission control transistor 202 and the write transistor 203. The silicide 405 can be arranged in, among the diffusion regions 308, 315, and 317 functioning as the source region or the drain region of the light emission control transistor 202 and the write transistor 203, the diffusion region not shared with the driving transistor 201 and the reset transistor 204. The silicide 405 is also arranged in each of the gate electrodes 311, 309, 313, and 316 of the driving transistor 201, the light emission control transistor 202, the write transistor 203, and the reset transistor 204. The silicides 404 and 405 are formed in the gate electrode, the drain region, and the source region where no silicide protection 407 exists. For example, a silicon oxide film is used as the silicide protection 407. In this embodiment, the driving transistor 201 is arranged between the light emission control transistor 202 and the light emitting element 200. However, in some cases, for example, the light emission control transistor 202 may be arranged between the driving transistor 201 and the light emitting element 200. In this case, the silicide 404 is arranged in the diffusion region functioning as the source region or the drain region of the light emission control transistor 202. Further, the silicide 405 is arranged in, among the diffusion regions functioning as the source region or the drain region of the driving transistor 201, the diffusion region not shared with the light emission control transistor 202.

Here, the materials of the silicides 404 and 405 are selected such that the diffusion coefficient of the metal contained in the silicide 404 to silicon is smaller than the diffusion coefficient of the metal contained in the silicide 405 to silicon. For example, the silicide 404 may contain titanium (Ti), and the silicide 405 may contain cobalt (Co) or nickel (Ni). Hence, the silicide 404 may be titanium silicide, and the silicide 405 may be cobalt silicide or nickel silicide.

In this embodiment, the silicide 404 is arranged in each of the diffusion regions 310, 312, and 314 functioning as the source region or the drain region of the driving transistor 201 and the reset transistor 204, and the silicide 405 is not arranged therein. If the silicides 405 exist in the diffusion regions 310, 312, and 314, since the diffusion coefficient of the metal forming the silicide 405 is larger than that of the metal forming the silicide 404, metal atoms can more easily reach near the depletion layer between the n-type well layer 402 and the p-type diffusion regions 310, 312, and 314. Further, although not shown, metal atoms can also diffuse in the boundary between the diffusion regions 310, 312, and 314 and the insulating isolation structure 403, and this can accelerate growth of the silicide. Due to these factors, an off-leakage current increases and causes light emission of the light emitting element 200, and this can lead to a decrease in contrast of the light emitting device 101.

To the contrary, in this embodiment, by using a metal having a small diffusion coefficient for the silicide 404, metal diffusion from the silicide 404 into the diffusion regions 310, 312, and 314 of the driving transistor 201 and the reset transistor 204 is suppressed. As a result, the amount of metal entering the depletion layer between the region 312 of the driving transistor 201 and the well layer 402 decreases, and an off-leakage current via the level of metal can be suppressed.

Further, in this embodiment, an insulating film is arranged as the silicide protection 407 so as to cover the diffusion regions 310, 312, and 314. Opening portions exposing the silicides 404 are provided in the silicide protection 407, and a conductive pattern 420 in contact with the silicide 404 is arranged in each opening portion. In this structure, the silicides 404 can be formed by, after forming the silicide protection 407 on the diffusion regions 310, 312, and 314, providing the opening portions, and annealing Ti used as the barrier metal of the connection wiring pattern. That is, in the orthogonal projection to the surface of the substrate where the pixel 103 is arranged, the silicide 404 is arranged to overlap the portion of the conductive pattern 420 arranged in the opening portion provided in the silicide protection 407. In other words, the silicide 404 is formed only in almost the bottom portion of the conductive pattern 420. Therefore, the silicide 404 and the region 406 for forming the LDD structure are not in contact with each other. On the other hand, the conductive pattern 420 is connected to each of the diffusion regions 308, 315, and 317 of the light emission control transistor 202 and the write transistor 203 via the silicide 405. As shown in FIG. 4, the silicide 405 is formed not only in the bottom portion of the conductive pattern 420 but also in the wide range of each of the diffusion regions 308, 315, and 317. Accordingly, in the orthogonal projection to the surface of the substrate where the pixel 103 is arranged, a value obtained by dividing the arrangement area of the silicide 404 by the area of the contact portion between the conductive pattern 420 and the silicide 404 is smaller than a value obtained by driving the arrangement area of the silicide 405 by the area of the contact portion between the conductive pattern 420 and the silicide 405. The silicide 405 and the region 406 for forming the LDD structure may not be in contact with each other also in the light emission control transistor 202 and the write transistor 203

With the arrangement described above, in the diffusion regions 310, 312, and 314 of the driving transistor 201 and the reset transistor 204, metal diffusion from the silicide 404 arranged in the bottom portion of the conductive pattern 420 to the region 406 of the LDD structure can be suppressed. Accordingly, the amount of metal entering the depletion layer formed near the region 406 can be decreased, and an off-leakage current between the source region and the drain region can also be reduced. Owing to this effect, the distance between the silicide 404 and the region 406 can be shortened. That is, it is also possible to suppress decrease of contrast, thereby obtaining the finer pixel 103 with a high resolution.

In the arrangement of this embodiment, the silicide 405 is arranged in each of the diffusion regions 308, 315, and 317 of the light emission control transistor 202 and the write transistor 203 that does not contribute to an off-leakage current to the light emitting element 200. Cobalt silicide or nickel silicide used for the silicide 405 can be formed to be stable with low resistance as compared to titanium silicide used for the silicide 404. Further, as has been described above, by arranging the silicide 405 in the wide region of each of the diffusion regions 308, 315, and 317, the lateral resistance in each of the source region and drain region where a current flows can be suppressed. In other words, the sheet resistance value of each of the diffusion regions 308, 315, and 317 of the light emission control transistor 202 and the write transistor 203 can be suppressed.

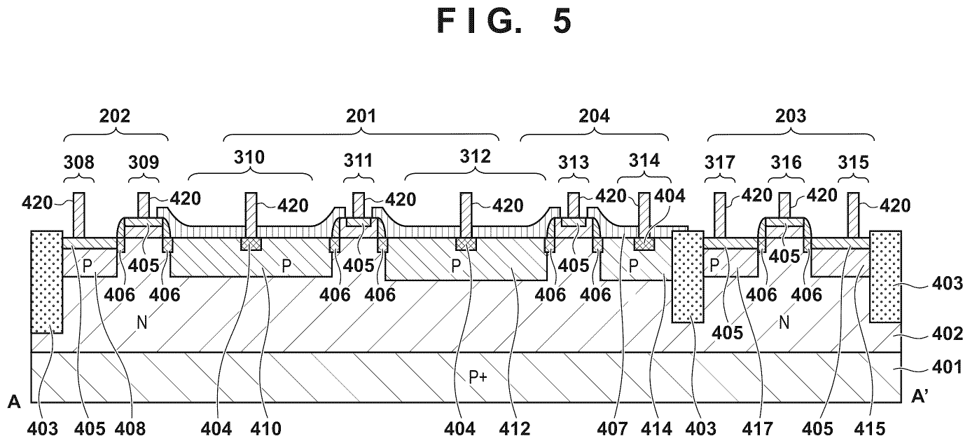

Here, as shown in FIG. 5, the silicide protection 407 may not be arranged in the light emission control transistor 202 and the write transistor 203 where the silicide 405 is arranged in each of the diffusion regions 308, 315, and 317. For example, the silicide protection 407 may not be provided in a region 109 where the light emission control transistor 202 and the write transistor 203 are arranged as shown in FIG. 2. The silicide protection 407 may be provided with an opening portion corresponding to the region 109, which is larger than the opening portions corresponding to the diffusion regions 310, 312, and 314 and the gate electrodes 311 and 313 of the driving transistor 201 and the reset transistor 204. In the arrangement shown in FIG. 5, the silicide 405 and the region 406 for forming the LDD structure may be in contact with each other in each of the light emission control transistor 202 and the write transistor 203.

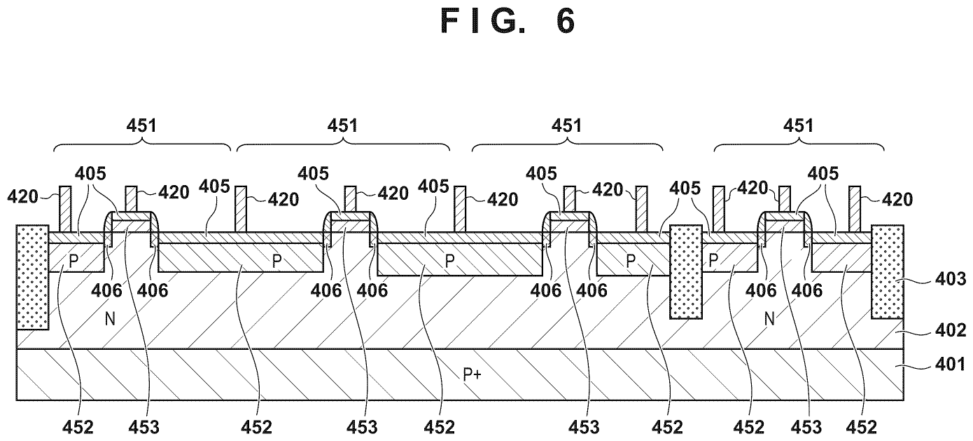

Further, also in the driving unit including the vertical scanning circuit 104 and the signal output circuit 105, as shown in FIG. 6, the silicide protection 407 may not be arranged, and the silicide 405 may be arranged in the whole surface of each of a gate electrode 453 and a diffusion region 452. For example, the silicide protection 407 may not be provided in a region 108 where the vertical scanning circuit 104 and the signal output circuit 105 are arranged as shown in FIG. 1. FIG. 6 shows PMOS transistors 451 each including the gate electrode 453 and the diffusion region 452. However, the present invention is not limited to this, and NMOS transistors may also be arranged in the vertical scanning circuit 104 and the signal output circuit 105 to form, for example, CMOS circuits with the PMOS transistors. For the NMOS transistor as well, the silicide 405 may be arranged to cover the whole exposed surface of each of the gate electrode and the diffusion region as shown in FIG. 6. As has been described above, cobalt silicide or nickel silicide used for the silicide 405 can be formed to be stable with low resistance. Further, by arranging the silicide 405 in the wide region of the diffusion region 452, the lateral resistance in each of the source region and drain region where a current flows can be suppressed. Thus, it is possible to suppress the sheet resistance value of the transistor 451 arranged in the driving unit including the vertical scanning circuit 104 and the signal output circuit 105, thereby improving the current driving capability of the transistor 451.

In this manner, by changing the metals used for the silicides 404 and 405, while suppressing the off-leakage current of each of the driving transistor 201 and the reset transistor 204 whose source region or drain region is connected to the light emitting element 200, the driving capability of each of the light emission control transistor 202 and the write transistor 203 is kept high. With this, it is possible to maintain the response speed of the pixel 103 and suppress decrease of contrast. That is, the light emitting device 101 having an excellent response speed and suppressing degradation of image quality can be obtained.

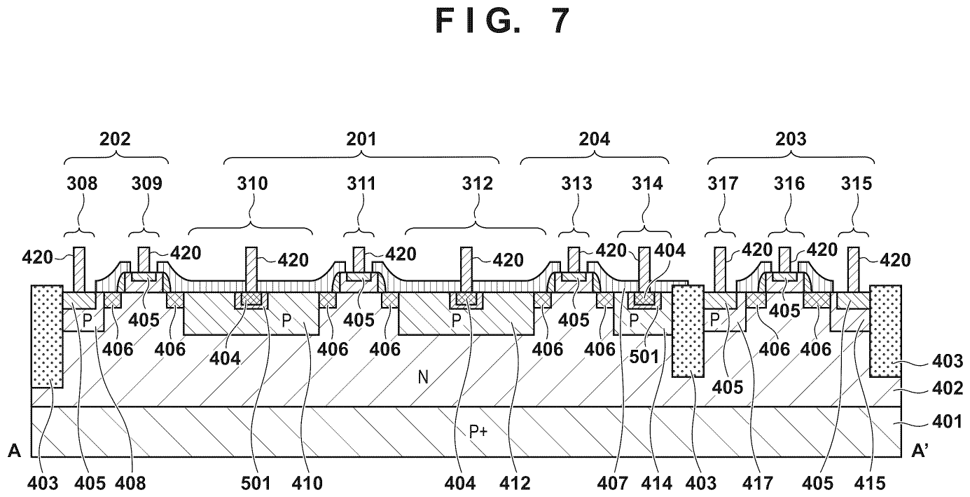

Next, with reference to FIG. 7, a modification of the arrangement of the light emitting device 101 will be described. FIG. 7 is a sectional view taken along the line A-A′ in FIG. 3. As compared to the sectional view shown in FIG. 4, the diffusion regions 310, 312, and 314 of the driving transistor 201 and the reset transistor 204 include the regions 410, 412, and 414, and a region 501 arranged between the region 412 and the silicide 404. The impurity concentration in the p-type regions 410, 412, and 414 is lower than the impurity concentration in the p-type region 501. The remaining arrangement may be similar to the arrangement shown in FIG. 4 described above, so that a description of the similar arrangement will be omitted.

In the arrangement shown in FIG. 7, the p-type region 501 having a higher impurity concentration than the regions 408, 415, and 417 is not arranged in the diffusion regions 308, 315, and 317 of the light emission control transistor 202 and the write transistor 203. However, the present invention is not limited to this, and the region 501 may be arranged between the silicide 405 and each of the region 408, 415, and 417. Similarly, a region corresponding to the region 501 may be arranged in each of the gate electrodes 309, 311, 313, and 316. In this embodiment, a description is given using the p-type transistors as described above, but n-type transistors may be used for the driving transistor 201, the light emission control transistor 202, the write transistor 203, and the reset transistor 204. In this case, the region 501 is an n-type region.

In this embodiment, the regions are formed such that the impurity concentration in the regions 410, 412, and 414 is lower than the impurity concentration in the regions 408, 415, and 417 of the diffusion regions 308, 315, and 317. With this, in the diffusion regions 310, 312, and 314, the electric field intensity in the depletion layer generated between the regions 410, 412, and 414 and the n-type well layer 402 is relaxed, and an off-leakage current can be suppressed. At this time, the impurity concentration in the region 406 may be lower than the impurity concentration in the regions 410, 412, and 414. Further, the impurity concentration in the regions 406 arranged in the driving transistor 201 and the reset transistor 204 may be set lower than the impurity concentration in the regions 406 arranged in the light emission control transistor 202 and the write transistor 203. With this, the off-leakage current in each of the driving transistor 201 and the reset transistor 204 can be further decreased.

If the impurity concentration in the regions 410, 412, and 414 of the diffusion regions 310, 312, and 314 of the driving transistor 201 and the reset transistor 204 is decreased, the difference in work function between the silicide 404 and silicon increases. As a result, the contact resistance between the silicide 404 and each of the diffusion regions 310, 312, and 314 (regions 410, 412, and 414) increases. Therefore, impurity injection is selectively performed to make the region 501 in contact with the silicide 404 a p-type impurity layer with a high concentration of 1×10¹⁸ atoms/cm³ or more. Thus, the contact resistance between the silicide 404 and each of the diffusion regions 310, 312, and 314 can be suppressed. The region 501 is selectively formed in the portion in contact with the silicide 404. Hence, it is possible to suppress a rise of the impurity concentration in the diffusion regions 310 and 312 (regions 410 and 412) near the gate electrodes 311 and 313 of the driving transistor 201 and the reset transistor 204. With this, it is possible to suppress an off-leakage current between the source region and drain region of each of the driving transistor 201 and the reset transistor 204.

The arrangement shown in FIG. 7 can further decrease the off-leakage current flowing to the anode of the light emitting element 200, as compared to the arrangement shown in FIG. 4. Accordingly, a low contact resistance can be obtained in each of the driving transistor 201 and the reset transistor 204 while suppressing decrease of contrast of the light emitting device 101. That is, the driving capability of each of the driving transistor 201 and the reset transistor 204 can be improved. As a result, it is possible to obtain the light emitting device 101 having a more excellent response speed and suppressing degradation of image quality.

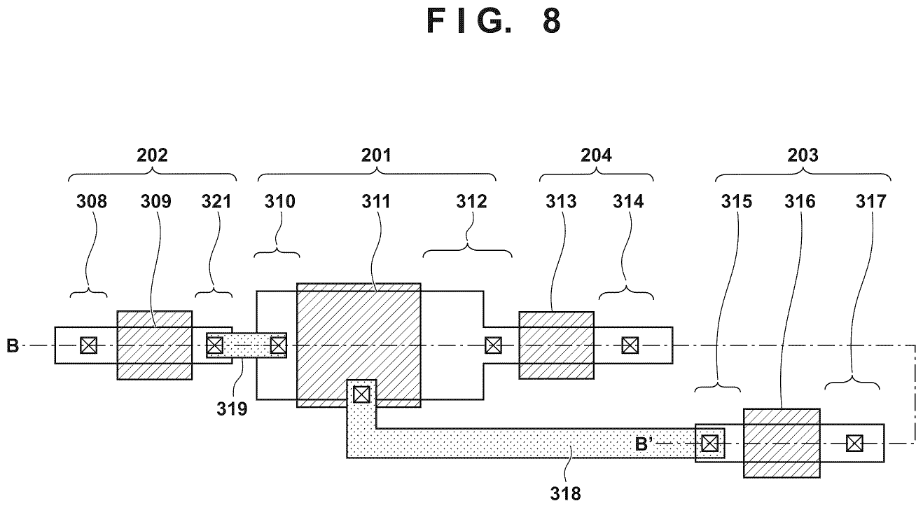

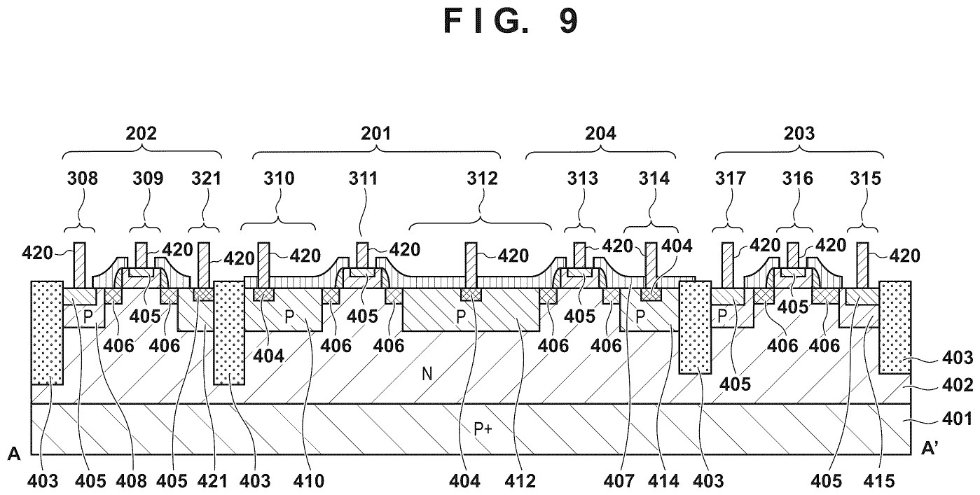

Next, with reference to FIGS. 8 and 9, a modification of the light emitting device 101 shown in FIGS. 3 and 4 will be described. FIG. 8 is a circuit diagram showing an example of the arrangement of the pixel 103 of the light emitting device 101. FIG. 9 is a sectional view taken along a line B-B′ in FIG. 8. In this embodiment, the driving transistor 201 and the light emission control transistor 202 are isolated by the insulating isolation structure 403 using the STI structure. With this, an independent diffusion region 321 functioning as a drain region is arranged in the light emission control transistor 202, which shares its drain region with the source region of the driving transistor 201 in FIGS. 3 and 4. The silicide 405 is arranged in the diffusion region 321 of the light emission control transistor 202 whose source region or drain region is not connected to the light emitting element 200. As shown in FIGS. 8 and 9, the insulating isolation structure 403 is arranged between the diffusion region 310 of the driving transistor 201 and the diffusion region 321 of the light emission control transistor 202, which are electrically connected to each other. Therefore, as shown in FIG. 8, the diffusion region 310 of the driving transistor 201 is connected to the diffusion region 321 of the light emission control transistor 202 by a conductive pattern 319. The remaining arrangement may be similar to the arrangement shown in FIGS. 3 and 4 described above, so that a description of the similar arrangement will be omitted.

As shown in the sectional view of FIG. 9, the light emission control transistor 202 is electrically isolated from the driving transistor 201 and the reset transistor 204 by the insulating isolation structure 403. In addition, the write transistor 203 is electrically isolated from the driving transistor 201 and the reset transistor 204 by the insulating isolation structure 403. That is, among the plurality of transistors arranged in the pixel 103 to operate the light emitting element 200, the transistor where the silicide 404 is arranged is isolated, by the STI structure, from the transistor where the silicide 405 is arranged. With this, diffusion of the metal used for the silicide 405 into the diffusion regions 310, 312, and 314 of the driving transistor 201 and the reset transistor 204 is further suppressed, and diffusion of the metal forming the silicide 405 into the depletion layer between the n-type well layer 402 and the p-type diffusion regions 310, 312, and 314 decreases. Thus, an off-leakage current can be reduced. As compared to the arrangement shown in FIGS. 3 and 4, the arrangement shown in FIGS. 8 and 9 can reduce the off-leakage current flowing from the diffusion region 312 of the driving transistor 201 to the anode of the light emitting element 200. As a result, degradation of image quality of the light emitting device 101 caused by decrease of contrast can be suppressed.

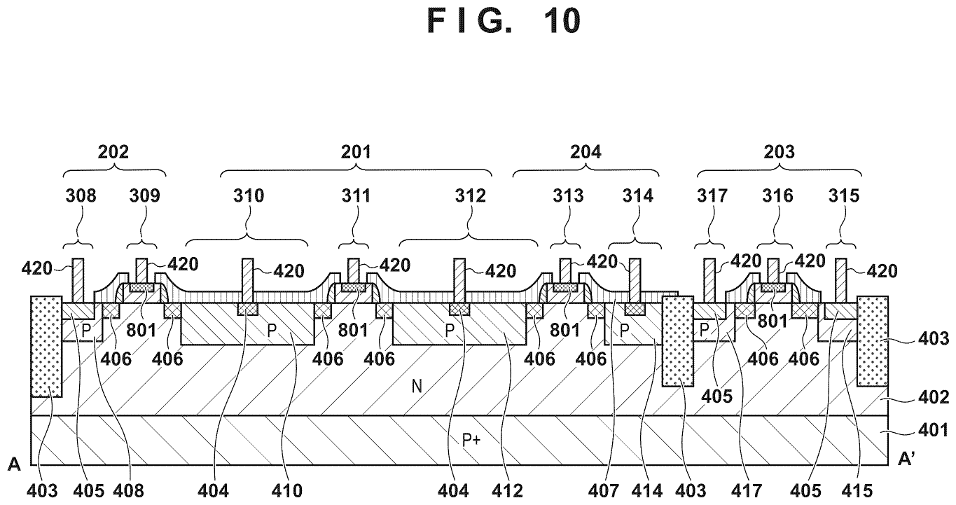

Next, with reference to FIG. 10, a modification of the arrangement of the light emitting device 101 will be described. FIG. 10 is a sectional view taken along the line A-A′ shown in FIG. 3. In the arrangement shown in FIG. 4, the silicide 405 arranged in each of the gate electrodes 311, 309, 316, and 313 of the driving transistor 201, the light emission control transistor 202, the write transistor 203, and the reset transistor 204 is the same as the silicide 405 arranged in each of the diffusion regions 310, 312, and 314 of the light emission control transistor 202 and the write transistor 203. On the other hand, in the arrangement shown in FIG. 10, a silicide 801 is arranged in each of the gate electrodes 311, 309, 316, and 313, which contains a metal different from the metal contained in the silicide 405 arranged in each of the diffusion regions 310, 312, and 314. The remaining arrangement may be similar to the arrangement shown in FIG. 4 described above, so that a description of the similar arrangement will be omitted.

The diffusion coefficient of the metal contained in the silicide 404 to silicon is smaller than the diffusion coefficient of the metal contained in each of the silicide 405 and the silicide 801 to silicon. As has been described above, the silicide 404 may contain titanium. On the other hand, the silicide 405 may contain cobalt, and the silicide 801 may contain nickel. That is, the silicide 404 may be titanium silicide, the silicide 405 may be cobalt silicide, and the silicide 801 may be nickel silicide.

Nickel silicide enables a fine pattern with more stable and lower resistance than cobalt silicide. Therefore, nickel silicide is used for the silicide 801 arranged in each of the gate electrodes 311, 309, 316, and 313 of the driving transistor 201, the light emission control transistor 202, the write transistor 203, and the reset transistor 204. With this, the sheet resistance value of each of the gate electrodes 311, 309, 316, and 313 decreases, and the driving capability of each transistor improves. As a result, the light emitting device 101 capable of operating at higher speed can be implemented. In addition, since the arrangement shown in FIG. 10 uses the silicides 404 and 405, an off-leakage current can be reduced as in the arrangement shown in FIG. 4. As a result, the light emitting device 101 having an excellent response speed and suppressing degradation of image quality can be obtained.

In the respective arrangements described above, descriptions have been given while taking titanium, cobalt, and nickel as examples of metals used for the silicides 404, 405, and 801, but the metals are not limited to those. For example, in consideration of the above-described diffusion coefficient to silicon, other metals such as platinum and palladium may be used for the silicides 404, 405, and 801.

The arrangement shown in FIG. 7, the arrangement shown in FIGS. 8 and 9, and the arrangement shown in FIG. 10 may be used in combination, as appropriate. For example, the region 501 may be added to the arrangement shown in FIGS. 8 and 9 or the arrangement shown in FIG. 10. Alternatively, for example, the silicide 801 shown in FIG. 10 may be arranged in each of the gate electrodes 311, 309, 316, and 313 in the arrangement shown in FIG. 7 or the arrangement shown in FIGS. 8 and 9.

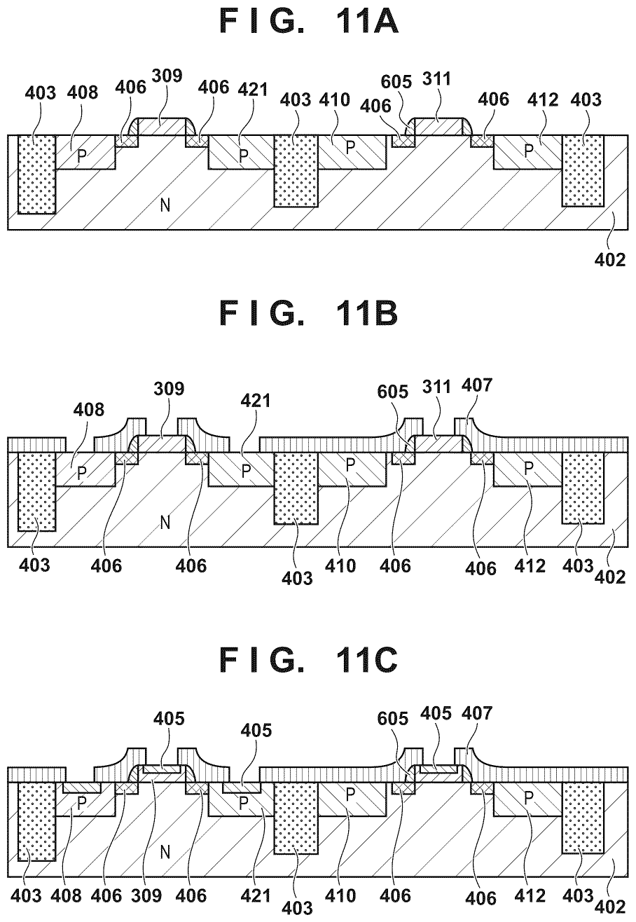

Next, a manufacturing method of the light emitting device 101 described above will be exemplarily described with reference to FIGS. 11A to 14B. Here, the driving transistor 201 is exemplarily shown as the transistor where the above-described silicide 404 is arranged in the diffusion region which functions as the source region or the drain region. Further, the light emission control transistor 202 is exemplarily shown as the transistor where the above-described silicide 405 is arranged in the diffusion region which functions as the source region or the drain region. However, the transistors are not limited to these, and each transistor described above can be similarly formed.

First, the insulating isolation structure 403 using the STI structure is formed in the well layer 402 on the substrate 401. Then, in a state in which a predetermined region is protected using a photoresist or the like, for example, multi-step ion implantation is performed to form the regions 410 and 412 of the diffusion regions 310 and 312 and the regions 408 and 421 of the diffusion regions 308 and 321. Thereafter, gate insulating films and the gate electrodes 311 and 309 are formed. Further, n-type or p-type light doping or HALO ion implantation is executed to form the region 406 for forming the LDD structure. Annealing is performed after the ion implantation to activate the respective regions. A state in which a sidewall 605 is formed on the side wall of each of the gate electrodes 311 and 309 is shown in FIG. 11A.

Then, as shown in FIG. 11B, the silicide protection 407 is formed. The silicide protection 407 is formed as follows. First, an insulating film using silicon oxide or silicon nitride is deposited on the structure shown in FIG. 11A. The insulating film made of silicon oxide or silicon nitride can be deposited using a low pressure CVD method or the like. Then, a photoresist is formed at a predetermined position using a photolithography process to expose the region where the silicide 405 is formed, and the insulating film not covered with the photoresist is etched. At this time, no opening is formed at positions corresponding to the diffusion regions 310 and 312 (regions 410 and 412) which will function as the source region and drain region of the driving transistor 201 connected to the light emitting element 200, thereby preventing formation of the silicide 405 in each of the diffusion regions 310 and 312 (regions 410 and 412).

Then, a metal to form the silicide 405 is deposited using sputtering or the like. At this time, for example, cobalt is deposited. After the deposition of cobalt, for example, annealing is performed at about 400° C. to 600° C., and unreacted cobalt is etched. Thereafter, for example, additional annealing is performed at 600° C. to 900° C., thereby forming the silicide 405 using cobalt silicide. The sectional view at this time is shown in FIG. 11C.

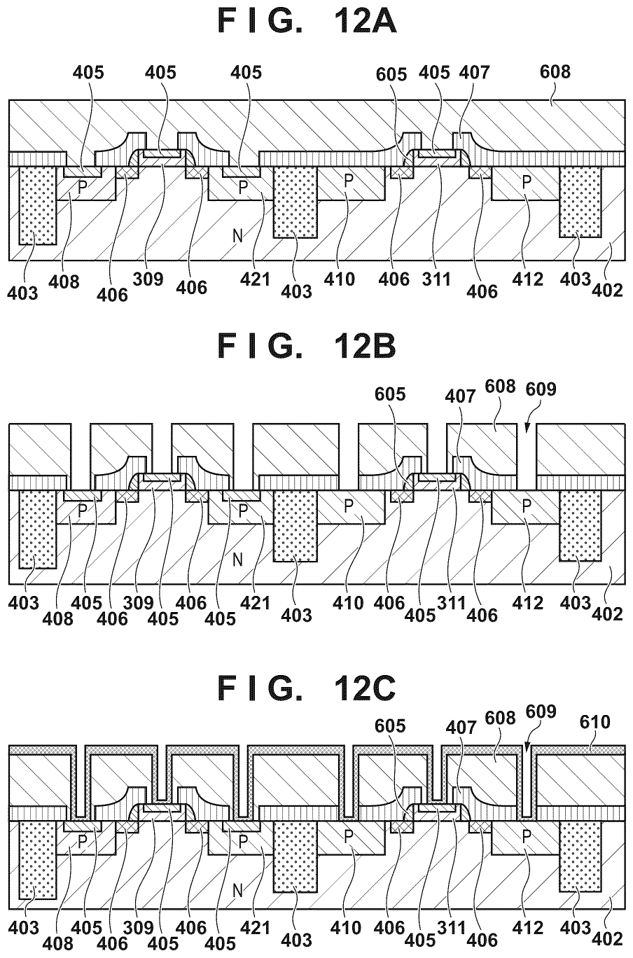

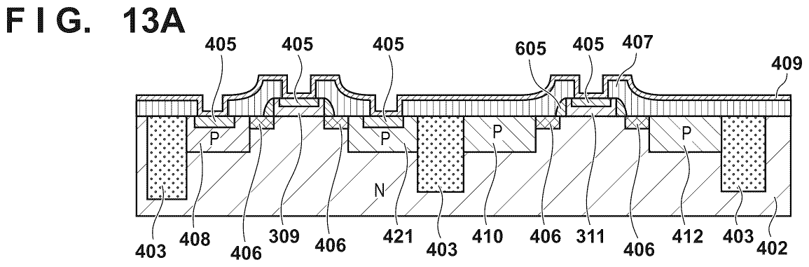

Then, an insulating film 608 is deposited as shown in FIG. 12A. The insulating film 608 may be deposited using a low pressure CVD method or an HDP-CVD method. The same material or different materials may be used for the silicide protection 407 and the insulating film 608. Each of the silicide protection 407 and the insulating film 608 may be a single layer film, or a stacked film formed by stacking insulating layers using different materials. Further, an additional insulating film may be arranged between the silicide protection 407 and the insulating film 608. For example, as shown in FIG. 13A, after forming the silicide protection 407 using silicon oxide, the silicide 405 is formed, and silicon nitride is deposited as an additional insulating film 409 on the silicide protection 407 and the silicide 405. Further, as shown in FIG. 13B, silicon oxide may be arranged as an insulating film 618 on the insulating film 409. In this case, it can be said that the insulating film 608 is a stacked film of the insulating film 409 using silicon nitride and the insulating film 618 using silicon oxide.

After the insulating film 608 is formed, as shown in FIG. 12B, holes 609 for arranging the contact plugs (conductive patterns 420) for connecting the diffusion regions 310, 312, 308, and 321 (regions 410, 412, 408, and 421) and the wiring pattern arranged in the wiring layer described above are formed. The hole 609 can be formed by forming a photoresist at a predetermined position using a photolithography process and, for example, dry-etching the insulating film 608 not covered with the photoresist.

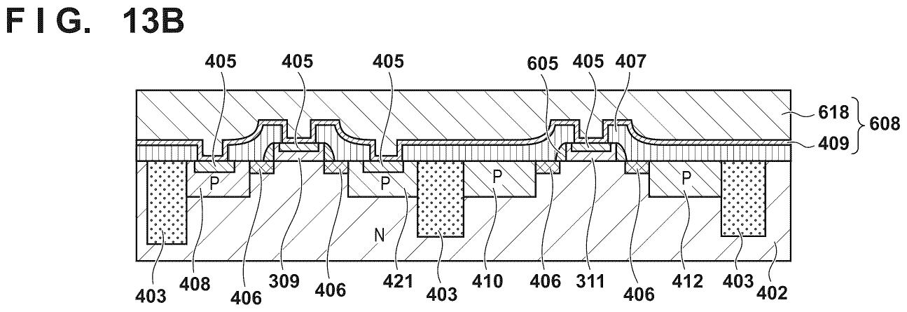

After the holes 609 are formed, as shown in FIG. 12C, titanium is deposited as a barrier metal 610. The barrier metal 610 can be deposited using sputtering or a CVD method. Following the deposition of the barrier metal 610, annealing is executed. With the annealing, as shown in FIG. 14A, the silicide 404 (titanium silicide) is formed in the bottom portion of the hole 609 in each of the diffusion regions 310 and 312 (regions 410 and 412). On the other hand, at this time, titanium silicide is not formed in the bottom of the hole 609 in each of the diffusion regions 308 and 321 (regions 408 and 421) where the silicide 405 has already been formed.

Then, as shown in FIG. 14B, for example, the hole 609 is filled using a conductive member 612 such as tungsten, and the above-described conductive pattern 420 is thus formed. Thereafter, for example, multiple wiring layers and the like are formed, and the light emitting device 101 is thus formed.

It has been described above that the silicide 405 is formed using cobalt in the above-described step, but nickel may be used as described above. In this case, in the step described with reference to FIG. 11C, nickel is deposited instead of cobalt. As has been described above, metals used for the silicides 404 and 405 are not limited to titanium, cobalt, and nickel. While considering the diffusion coefficient to silicon, other metals may be used for the silicides 404 and 405.

In the light emitting device 101 manufactured by the steps described above, the silicide 404 formed in each of the diffusion regions functioning as the source region and drain region of the transistor connected to the light emitting element 200 uses a metal having a lower diffusion coefficient than that formed in the diffusion regions functioning as the source region and drain region of the transistor not connected to the light emitting element 200. Accordingly, an off-leakage current is reduced, and decrease of contrast is suppressed. As a result, the light emitting device 101 having higher image quality can be obtained.

The light emitting device 101 need not always be formed in accordance with the above-described manufacturing method and step order, and replacement, change, and the like of various steps are possible. The above-described process merely shows some aspects to which the present invention can be applied, and does not prevent appropriate modifications and changes in the range without departing from the scope of the present invention.

Here, an example of the arrangement of each constituent element of the light emitting device 101 will be described. In the light emitting device 101, the pixel array 102 where the plurality of pixels 103 are arranged, and the driving unit including the vertical scanning circuit 104, the signal output circuit 105, and the like for driving the light emitting element 200 may be arranged on one substrate. For example, all the constituent elements of the light emitting device 101 may be arranged on one substrate. However, the arrangement of the light emitting device 101 is not limited to this. For example, the light emitting device 101 may be formed by stacking the substrate where at least the light emitting element 200 of the pixel 103 is arranged and the substrate where the driving unit includes the vertical scanning circuit 104, the signal output circuit 105, and the like for driving the light emitting element.

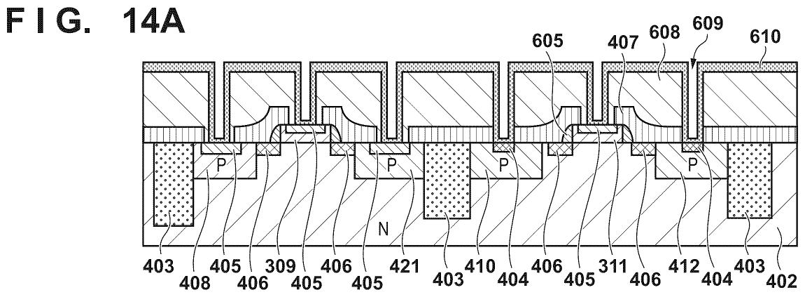

FIG. 15 shows an example of the circuit arrangement of the pixel 103 of the light emitting device 101. FIG. 15 shows an example of the arrangement of the pixel 103 in a case where the light emitting device 101 is formed including substrates 511 and 521. The driving transistor 201 and the reset transistor 204 are arranged on the substrate 511. The light emission control transistor 202 and the write transistor 203 are arranged on the substrate 521. The driving unit including the vertical scanning circuit 104, the signal output circuit 105, and the like may be arranged on, for example, the substrate 521. Alternatively, for example, the driving unit including the vertical scanning circuit 104, the signal output circuit 105, and the like may be arranged on another substrate different from the substrates 511 and 521.

A bonding portion 518a is arranged in a current path between the driving transistor 201 arranged on the substrate 511 and the write transistor 203 arranged on the substrate 521. A bonding portion 518b is arranged in a current path between the driving transistor 201 arranged on the substrate 511 and the light emission control transistor 202 arranged on the substrate 521. The gate electrode of the driving transistor 201 arranged on the substrate 511 is electrically connected to a bonding pad 513a via a conductive path (for example, a wiring pattern, a plug, and the like). The diffusion region functioning as the drain region of the write transistor 203 arranged on the substrate 521 is electrically connected to a bonding pad 523a via a conductive path (for example, a wiring pattern, a plug, and the like). The bonding pad 513a and the bonding pad 523a are bonded to each other, thereby forming the bonding portion 518a. The diffusion region functioning as the source region of the driving transistor 201 arranged on the substrate 511 is electrically connected to a bonding pad 513b via a conductive path (for example, a wiring pattern, a plug, and the like). The diffusion region functioning as the drain region of the light emission control transistor 202 arranged on the substrate 521 is electrically connected to a bonding pad 523b via a conductive path light (for example, a wiring pattern, a plug, and the like). The bonding pad 513b and the bonding pad 523b are bonded to each other, thereby forming the bonding portion 518b.

Each of the bonding pads 513 and 523 may be made of copper (Cu). In this case, the bonding portion 518 can use Cu—Cu bonding. However, the bonding method of the substrate 511 and the substrate 521 is not limited to Cu—Cu bonding. As long as signal exchange between the substrate 511 and the substrate 521 is possible, an appropriate method may be used for bonding between the substrate 511 and the substrate 521.

In the arrangement shown in FIG. 15, the silicide 404 is arranged in the diffusion region functioning as the source region or drain region of each of the driving transistor 201 and the reset transistor 204 arranged on the substrate 511. Further, the silicide 405 can be arranged in the gate electrode of each of the driving transistor 201 and the reset transistor 204. On the other hand, when forming the light emission control transistor 202 and the write transistor 203 arranged on the substrate 521, the above-described silicide protection 407 is not formed, and the silicide 405 alone may be arranged in the gate electrode and diffusion region functioning as the source region or drain region of each of the light emission control transistor 202 and the write transistor 203. Alternatively, as described above, when the driving unit including the vertical scanning circuit 104, the signal output circuit 105, and the like is arranged on the substrate 521, the silicide 405 alone may be arranged in the gate electrode and the diffusion region functioning as the source region or drain region of the transistor arranged in the driving unit. In this case, when forming the transistor of the driving unit, the silicide protection 407 may not be formed.

On the substrate 511, when forming a transistor, it may be necessary to form two kinds of silicides 404 and 405. On the other hand, one kind of silicide (for example, silicide 405) alone may be formed for the transistor arranged on the substrate 521. Accordingly, the process productivity upon forming a circuit on the substrate 521 can be improved. Alternatively, for example, on the substrate 511, the silicide 404 including the gate electrode may be formed when forming a transistor, and on the substrate 521, the silicide 405 may be formed when forming a transistor. With this, in each of the substrates 511 and 521, the silicide formation process is unified, and the productivity can be improved. In this manner, respective constituent elements of the light emitting device 101 may be arranged on the substrates 511 and 521 different from each other in accordance with the kinds of the silicides 404 and 405 arranged in the transistors. The remaining arrangement may be similar to the arrangement shown in FIG. 4 described above, so that a description of the similar arrangement will be omitted.

The organic EL element has been exemplified as the light emitting element 200 but the light emitting element 200 is not limited to this. The light emitting element 200 can be applied to the general light emitting device using a current-driven electro-optical element (light emitting element) whose light emission luminance changes in accordance with the value of a current flowing through the element, such as an inorganic EL element, an LED element, or a semiconductor laser element.

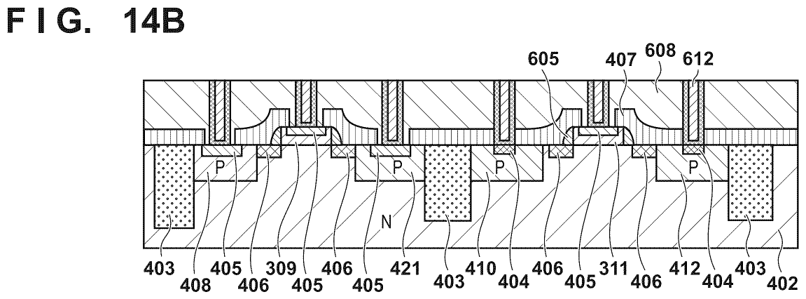

Here, application examples in which the light emitting device 101 according to the embodiment is applied to a display device, a photoelectric conversion device, an electronic apparatus, an illumination device, a moving body, and a wearable device will be described with reference to FIGS. 16 to 22A and 22B.

FIG. 16 is a schematic view showing an example of the display device using the light emitting device 101 of this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display device 1000 is not a portable apparatus. Even when the display device 1000 is a portable apparatus, the battery 1008 need not be provided at this position. The light emitting device 101 according to the embodiment can be applied to the display panel 1005. The display region of the light emitting device 101 functioning as the display panel 1005 operates in a state in which it is connected to the active elements such as transistors arranged on the circuit board 1007.

The display device 1000 shown in FIG. 16 can be used for a display unit of a photoelectric conversion device (image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

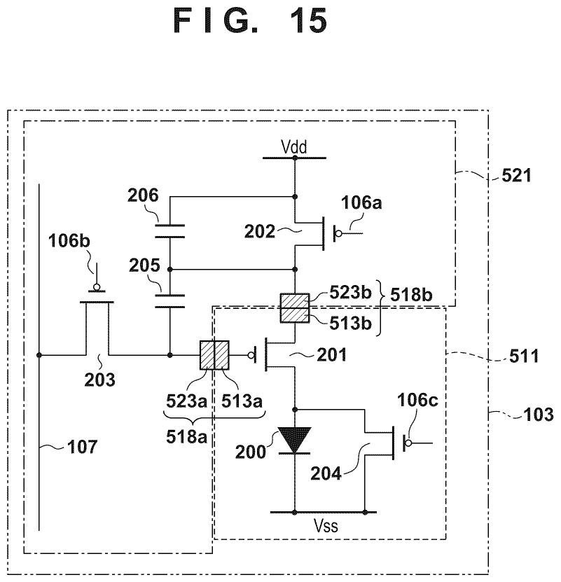

FIG. 17 is a schematic view showing an example of the photoelectric conversion device using the light emitting device 101 of this embodiment. A photoelectric conversion device 1100 can include a viewfinder 1101, a rear display 1102, an operation unit 1103, and a housing 1104. The photoelectric conversion device 1100 can also be called an image capturing device. The light emitting device 101 according to this embodiment can be applied to the viewfinder 1101 or the rear display 1102 as a display unit. In this case, the light emitting device 101 can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time in many cases, so the information should be displayed as soon as possible. Therefore, the light emitting device 101 containing the organic light emitting material such as an organic EL element in the light emitting layer may be used for the viewfinder 1101 or the rear display 1102. This is so because the organic light emitting material has a high response speed. The light emitting device 101 using the organic light emitting material can be used for the devices that require a high display speed more suitably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device 101 may be applied to a display unit of an electronic apparatus. At this time, the display unit can have both a display function and an operation function. Examples of the portable terminal are a portable phone such as a smartphone, a tablet, and a head mounted display.

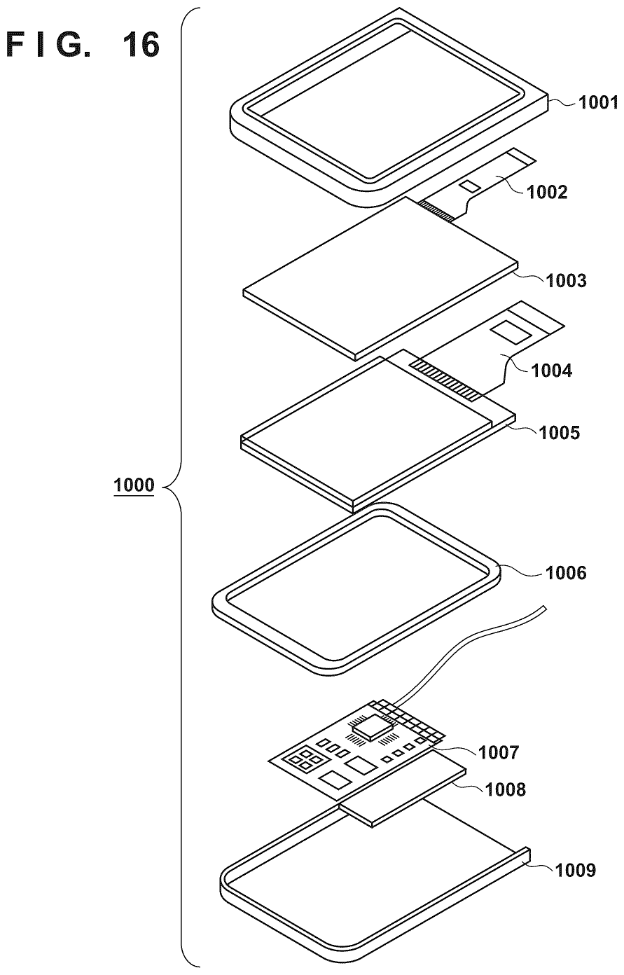

FIG. 18 is a schematic view showing an example of an electronic apparatus using the light emitting device 101 of this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device 101 according to this embodiment can be applied to the display unit 1201.

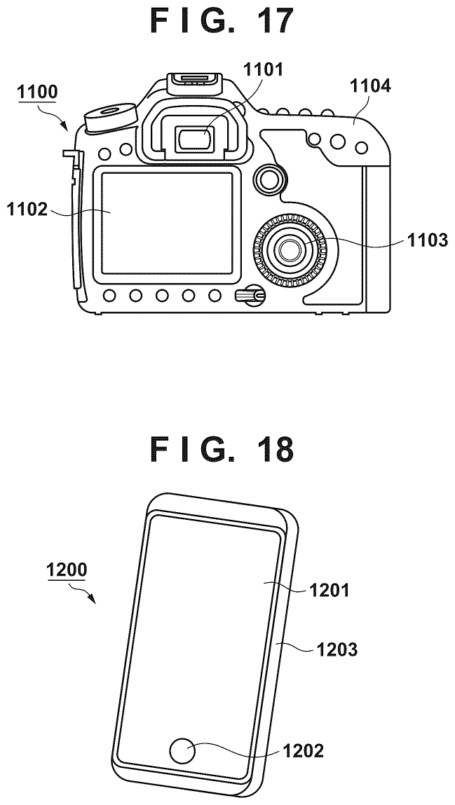

FIGS. 19A and 19B are schematic views showing examples of the display device using the light emitting device 101 of this embodiment. FIG. 19A shows a display device such as a television monitor or a PC monitor. A display device 1300 includes a frame 1301 and a display unit 1302. The light emitting device 101 according to this embodiment can be applied to the display unit 1302. The display device 1300 can include a base 1303 that supports the frame 1301 and the display unit 1302. The base 1303 is not limited to the form shown in FIG. 19A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 19B is a schematic view showing another example of the display device using the light emitting device 101 of this embodiment. A display device 1310 shown in FIG. 19B can be folded, and is a so-called foldable display device. The display device 1310 includes a first display unit 1311, a second display unit 1312, a housing 1313, and a bending point 1314. The light emitting device 101 according to this embodiment can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

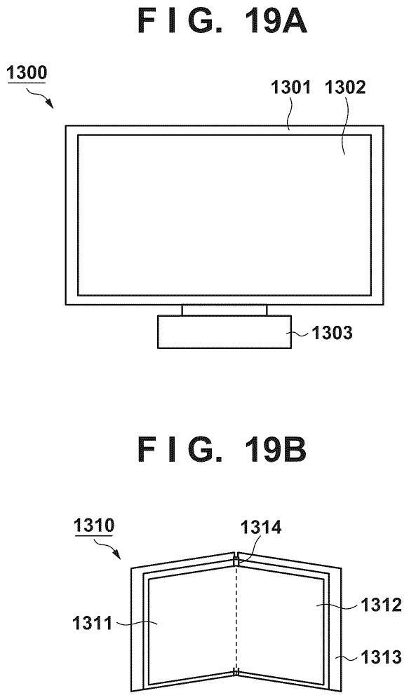

FIG. 20 is a schematic view showing an example of an illumination device using the light emitting device 101 according to this embodiment. An illumination device 1400 may include a housing 1401, a light source 1402, a circuit board 1403, an optical film 1404, and a light diffusion unit 1405. The light emitting device 101 according to this embodiment can be applied to the light source 1402. The optical film 1404 may be a filter that improves the color rendering property of the light source. The light diffusion unit 1405 can effectively diffuse light from the light source to illuminate a wide range for lighting up or the like. A cover may be provided in the outermost portion, as needed. The illumination device 1400 may include both the optical film 1404 and the light diffusion unit 1405, or may include only one of them.

The illumination device 1400 is, for example, a device that illuminates a room. The illumination device 1400 may emit light of white, day white, or any other color from blue to red. The illumination device 1400 may include a light control circuit for controlling the light color. The illumination device 1400 may include a power supply circuit connected to the light emitting device 101 which functions as the light source 1402. The power supply circuit is a circuit that converts an AC voltage into a DC voltage. Note that white light has a color temperature of 4200K, and day-white light has a color temperature of 5000K. The illumination device 1400 may also include a color filter. Further, the illumination device 1400 may include a heat dissipation portion. The heat dissipation portion releases the heat in the device to the outside of the device, and examples thereof include a metal having high specific heat, liquid silicon, and the like.

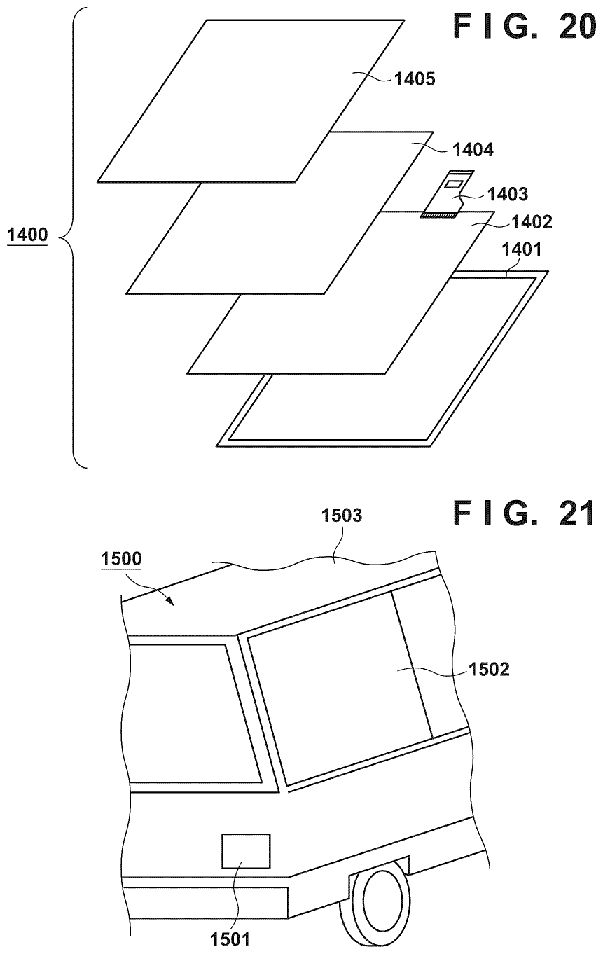

FIG. 21 is a schematic view showing an automobile including a tail lamp which is an example of the lighting unit for an automobile using the light emitting device 101 according to this embodiment. An automobile 1500 includes a tail lamp 1501, and may turn on the tail lamp 1501 when a brake operation or the like is performed. The light emitting device 101 according to this embodiment may be used in a head lamp as the lighting unit for an automobile. The automobile is an example of a moving body, and the moving body may be a ship, a drone, an aircraft, a railroad car, an industrial robot, or the like. The moving body may include a body and a lighting unit provided in the body. The lighting unit may inform the current position of the body.

The light emitting device 101 according to this embodiment can be applied to the tail lamp 1501. The tail lamp 1501 may include a protective member that protects the light emitting device 101 which functions as the tail lamp 1501. The protective member has a certain degree of strength, and can be made from any material as long as it is transparent. The protective member may be made from polycarbonate or the like. Further, the protective member may be made from polycarbonate mixed with furandicarboxylic acid derivative, acrylonitrile derivative, or the like.

The automobile 1500 may include a body 1503 and windows 1502 attached thereto. The window may be a window for checking the front or rear of the automobile, or may a transparent display. The light emitting device 101 according to this embodiment may be used in the transparent display. In this case, the constituent materials of the electrodes and the like of the light emitting device 101 are formed by transparent members.

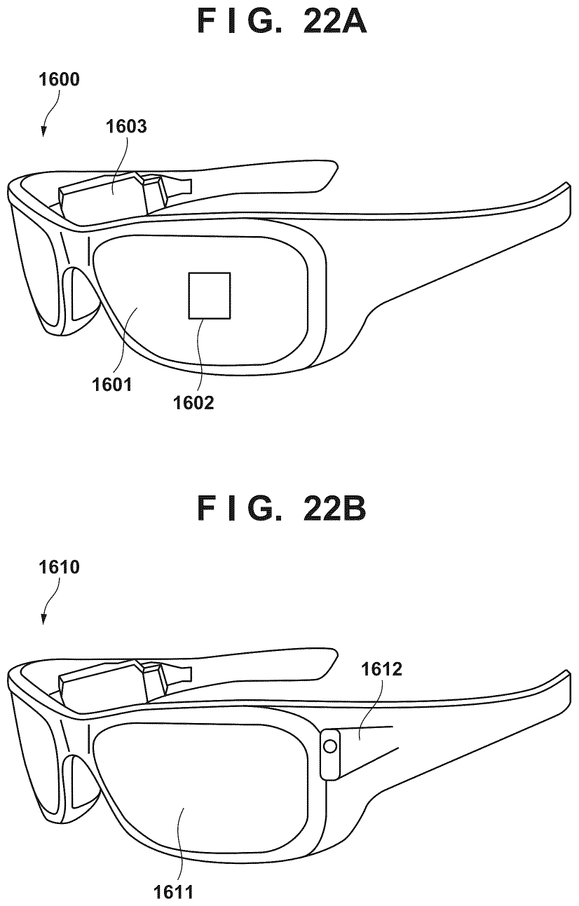

Further application examples of the light emitting device 101 according to this embodiment will be described with reference to FIGS. 22A and 22B. The light emitting device 101 can be applied to a system that can be worn as a wearable device such as smartglasses, a Head Mounted Display (HMD), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 22A. An image capturing device 1602 such as a CMOS sensor or an SPAD is provided on the front surface side of a lens 1601 of the glasses 1600. In addition, the light emitting device 101 according to this embodiment is provided on the back surface side of the lens 1601.

The glasses 1600 further include a control device 1603. The control device 1603 functions as a power supply that supplies electric power to the image capturing device 1602 and the light emitting device 101 according to each embodiment. In addition, the control device 1603 controls the operations of the image capturing device 1602 and the light emitting device 101. An optical system configured to condense light to the image capturing device 1602 is formed on the lens 1601.

Glasses 1610 (smartglasses) according to one application example will be described with reference to FIG. 22B. The glasses 1610 include a control device 1612, and an image capturing device corresponding to the image capturing device 1602 and the light emitting device 101 are mounted on the control device 1612. The image capturing device in the control device 1612 and an optical system configured to project light emitted from the light emitting device 101 are formed in a lens 1611, and an image is projected to the lens 1611. The control device 1612 functions as a power supply that supplies electric power to the image capturing device and the light emitting device 101, and controls the operations of the image capturing device and the light emitting device 101. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 101 according to an embodiment of the present invention can include an image capturing device including a light receiving element, and control a displayed image based on the line-of-sight information of the user from the image capturing device.

More specifically, the light emitting device 101 decides a first visual field region at which the user is gazing and a second visual field region other than the first visual field region based on the line-of-sight information. The first visual field region and the second visual field region may be decided by the control device of the light emitting device 101, or those decided by an external control device may be received. In the display region of the light emitting device 101, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device 101, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 101, the image capturing device, or an external device. If the external device holds the AI program, it is transmitted to the light emitting device 101 via communication.

When performing display control based on line-of-sight detection, smartglasses further including an image capturing device configured to capture the outside can be applied. The smartglasses can display captured outside information in real time.

According to the present invention, a technique advantageous in suppressing degradation of image quality can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A light emitting device in which a pixel including a light emitting element and a plurality of transistors configured to operate the light emitting element are arranged on a substrate, wherein
the plurality of transistors comprise a first transistor including one of a source region and a drain region connected to the light emitting element, and a second transistor including a source region and a drain region not connected to the light emitting element,
a first silicide is arranged in a first diffusion region functioning as one of the source region and the drain region of the first transistor,
a second silicide is arranged in a second diffusion region functioning as one of the source region and the drain region of the second transistor, and
a diffusion coefficient of a metal contained in the first silicide to silicon is smaller than a diffusion coefficient of a metal contained in the second silicide to silicon.

2. The light emitting device according to claim 1, wherein
an insulating film is arranged to cover the first diffusion region,
an opening portion exposing the first silicide is provided in the insulating film,
a conductive pattern in contact with the first silicide is arranged in the opening portion, and
in an orthogonal projection to a surface of the substrate where the pixel is arranged, the first silicide is arranged to overlap a portion of the conductive pattern arranged in the opening portion.

3. The light emitting device according to claim 2, wherein
the second diffusion region is connected to a second conductive pattern via the second silicide, and
in the orthogonal projection to the surface, a value obtained by dividing an arrangement area of the first silicide by an area of a contact portion between the conductive pattern and the first silicide is smaller than a value obtained by dividing an arrangement area of the second silicide by an area of a contact portion between the second conductive pattern and the second silicide.

4. The light emitting device according to claim 1, wherein
the first diffusion region includes a first region, and a second region arranged between the first region and the first silicide, and
an impurity concentration in the first region is lower than an impurity concentration in the second region.

5. The light emitting device according to claim 4, wherein
the first diffusion region further includes a third region arranged between the first region and a channel region of the first transistor and having a lower impurity concentration than the first region.

6. The light emitting device according to claim 4, wherein
the impurity concentration in the first region is lower than an impurity concentration in the second diffusion region.

7. The light emitting device according to claim 4, wherein
the second diffusion region includes a fourth region, and a fifth region arranged between the fourth region and a channel region of the second transistor and having a lower impurity concentration than the fourth region, and
the impurity concentration in the first region is lower than an impurity concentration in the fourth region.

8. The light emitting device according to claim 7, wherein
the second silicide and the fourth region are not in contact with each other.

9. The light emitting device according to claim 7, wherein
the second silicide and the fifth region are in contact with each other.

10. The light emitting device according to claim 1, wherein
the first diffusion region and the second diffusion region are electrically connected, and
an insulating isolation structure is arranged between the first diffusion region and the second diffusion region.

11. The light emitting device according to claim 1, wherein
the second silicide is not arranged in the first diffusion region.

12. The light emitting device according to claim 1, wherein
a third silicide is arranged in a gate electrode of each of the first transistor and the second transistor, and
the diffusion coefficient of the metal contained in the first silicide to silicon is smaller than a diffusion coefficient of a metal contained in the third silicide to silicon.

13. The light emitting device according to claim 12, wherein
the metal contained in the second silicide is the same as the metal contained in the third silicide.

14. The light emitting device according to claim 12, wherein
the metal contained in the second silicide is different from the metal contained in the third silicide.

15. The light emitting device according to claim 12, wherein
the first silicide contains titanium, and
the second silicide and the third silicide contain cobalt or nickel.

16. The light emitting device according to claim 1, wherein
the first silicide contains titanium, and
the second silicide contains cobalt or nickel.

17. The light emitting device according to claim 1, wherein
the substrate includes a first substrate and a second substrate,
the light emitting element and the first transistor are arranged on the first substrate, and
the second transistor is arranged on the second substrate.

18. The light emitting device according to claim 1, further comprising a driver configured to drive the pixel,
wherein the second silicide is arranged in a diffusion region functioning as one of a source region and a drain region of a transistor arranged in the driving unit.

19. A display device comprising the light emitting device according to claim 1, and an active element connected to the light emitting device.

20. A photoelectric conversion device comprising an optical unit including a plurality of lenses, an image sensor configured to receive light having passed through the optical unit, and a display unit configured to display an image,
wherein the display unit includes the light emitting device according to claim 1.

21. An electronic apparatus comprising a housing provided with a display unit, and a communication unit provided in the housing and configured to perform external communication,
wherein the display unit includes the light emitting device according to claim 1.

22. An illumination device comprising a light source, and at least one of a light diffusing unit and an optical film,
wherein the light source includes the light emitting device according to claim 1.

23. A moving body comprising a main body, and a lighting appliance provided in the main body,
wherein the lighting appliance includes the light emitting device according to claim 1.
